(19) United States
(12) Patent Application Publication
(10) Pub. No.: US 2025/0102814 A1
(43) Pub. Date: Mar. 27, 2025

(54) ELECTRONIC DEVICE INCLUDING LOAD BALANCING

(71) Applicant: Apple Inc., Cupertino, CA (US)

(72) Inventor: Paul X. Wang, Cupertino, CA (US)

(21) Appl. No.: 18/821,390

(22) Filed: Aug. 30, 2024

Related U.S. Application Data
(60) Provisional application No. 63/584,816, filed on Sep. 22, 2023.

(51) Int. Cl. G02B 27/01; G02C 3/00; G02C 5/20; G02C 11/00; H05K 5/00

(52) U.S. Cl. CPC G02B 27/0176; G02C 3/003; G02C 5/20; G02C 11/10; H05K 5/0086; G02B 2027/0154; G02B 2027/0178

(57) ABSTRACT

Optical devices including adjustment mechanisms for adjusting balance points thereof and methods of using the same are disclosed. In an example, a head-mountable electronic device includes a frame, a window coupled to the frame, a projector configured to guide light displayed at the window, and a securement arm extending from the frame. The securement arm includes a proximal portion connected to the frame, a distal portion connected to the proximal portion, and an expansion mechanism connecting the proximal portion to the distal portion, the expansion mechanism configured to extend the distal portion away from the proximal portion. The distal portion has a mass greater than a mass of the proximal portion.

### CROSS-REFERENCE TO RELATED APPLICATION

This application claims the benefit of U.S. Provisional Patent Application No. 63/584,816, filed 22 Sep. 2023, and entitled “ELECTRONIC DEVICE INCLUDING LOAD BALANCING,” the entire disclosure of which is hereby incorporated by reference.

### FIELD

The described embodiments relate generally to electronic devices. More particularly, the present embodiments relate to head-mountable electronic devices.

### BACKGROUND

Recent advances in portable computing have enabled head-mountable devices that provide augmented and virtual reality experiences to users. Various component of these devices, such as display screens, frames, securement arms, speakers, batteries, and other components, operate together to provide an immersive and comfortable experience. These devices can include a number of components, such as processors and displays that cause the devices to generally be front-heavy. This uneven weight distribution can be applied to a user's head during use of the device. Therefore, it is desirable to provide head-mountable devices that are more balanced and are comfortable for longer periods of use.

### SUMMARY

In at least one example of the present disclosure, a head-mountable electronic device can include a frame, a window coupled to the frame, a projector configured to guide light displayed at the window, and a securement arm extending from the frame. The securement arm can include a proximal portion connected to the frame, a distal portion connected to the proximal portion, and an expansion mechanism connecting the proximal portion to the distal portion. The expansion mechanism can be configured to extend the distal portion away from the proximal portion. The distal portion can have a mass greater than a mass of the proximal portion.

In one example, the distal portion can be configured to be disposed behind a user's ear when the head-mountable electronic device is donned by the user. The head-mountable electronic device can further include a first electronic component disposed in the distal portion and a second electronic component disposed in the proximal portion.

In some examples, the expansion mechanism can include an electric actuator. In some examples, the expansion mechanism can include a manual actuator. In some examples, the securement arm is a first securement arm, the distal portion is a first distal portion, and the expansion mechanism is a first expansion mechanism. The head-mountable electronic device can further include a second securement arm including a second proximal portion connected to a second distal portion at a second expansion mechanism. The head-mountable electronic device can further include a connection band including the first distal portion and the second distal portion. The connection band can extend from the first proximal portion to the second proximal portion.

In at least one example of the present disclosure, a head-mountable electronic device can include a frame, a window coupled to the frame, a waveguide configured to guide light displayed at the window, and a securement arm extending from the frame. The securement arm can include a proximal portion connected to the frame, a distal portion connected to the proximal portion, and an adjustment mechanism configured to move the distal portion distally relative to the frame. The proximal portion can include a first electronic component. The distal portion can include a second electronic component electrically coupled to the first electronic component.

In some examples, the adjustment mechanism can include a dial coupled to the distal portion and the proximal portion, and the dial can be configured to adjust an angle of the distal portion relative to the proximal portion when the dial is manipulated. In some examples, the adjustment mechanism can include a dial coupled to the distal portion or the proximal portion, and the dial can be configured to adjust a distance between the distal portion and the proximal portion when the dial is manipulated. In some examples, the adjustment mechanism can include a notched strap coupled to the distal portion and the proximal portion, and the notched strap can be configured to adjust a distance between the distal portion and the proximal portion when the distal portion is manipulated relative to the proximal portion.

In some examples, the adjustment mechanism can include a friction hinge pivotally attaching the distal portion to the proximal portion. In some examples, an inner surface of the distal portion can include a hair coupler. In some examples, the securement arm is a first securement arm, the head-mountable electronic device can further include a second securement arm extending from the frame, and the distal portion can extend from the first securement arm to the second securement arm.

In at least one example of the present disclosure, a head-mountable display device can include a frame, a window coupled to the frame; a projector configured to guide light displayed at the window, a first securement arm extending from the frame, the first securement arm including a first distal end, a second securement arm extending from the frame, the second securement arm including a second distal end, an adjustable ballast extending between and secured to the first distal end and the second distal end, and an adjustment mechanism configured to change a position of the ballast relative to the frame.

In some examples, the adjustment mechanism can be configured to adjust an angle of the adjustable ballast relative to the first securement arm and the second securement arm. In some examples, the adjustment mechanism can be configured to extend the adjustable ballast distally away from the first distal end and the second distal end. In some examples, the adjustment mechanism can include a friction fit between the adjustable ballast and the first distal end.

In some examples, the adjustment mechanism is a first adjustment mechanism, and the head-mountable display device can further include a second adjustment mechanism coupling the first securement arm to the frame. In some examples, the second adjustment mechanism can be configured to adjust an angle of the frame relative to the first securement arm.

### BRIEF DESCRIPTION OF THE DRAWINGS

The disclosure will be readily understood by the following detailed description in conjunction with the accompanying drawings, wherein like reference numerals designate like structural elements, and in which:

FIG. 1 shows a perspective view of an example of a head-mountable device;

FIG. 2 shows a side view of an example of a head-mountable device worn by a user;

FIG. 3 shows a side view of an example of a head-mountable device;

FIG. 4 shows a perspective view of an example of a head-mountable device;

FIG. 5 shows a side view of an example of an adjustment mechanism for a securement arm of a head-mountable device;

FIG. 6 shows a side view of an example of an adjustment mechanism for a securement arm of a head-mountable device;

FIG. 7 shows a top-down view of an example of a head-mountable device;

FIG. 8 shows a perspective view of an example of a band of a head-mountable device; and

FIG. 9 shows a side view of an example of a head-mountable device.

### DETAILED DESCRIPTION

Reference will now be made in detail to representative embodiments illustrated in the accompanying drawings. It should be understood that the following descriptions are not intended to limit the embodiments to one preferred embodiment. To the contrary, it is intended to cover alternatives, modifications, and equivalents as can be included within the spirit and scope of the described embodiments as defined by the appended claims.

The following disclosure relates to electronic devices. More particularly, the present disclosure relates to head-mountable electronic devices. In at least one example, a head-mountable device can include a frame and a securement arm extending from the frame. Examples of head-mountable devices can include optical devices (e.g., glasses, sunglasses, etc.) or virtual/augmented reality devices that include an optical component. In the case of augmented reality devices, optical eyeglasses can be worn on the head of a user such that optical lenses and/or optical displays are positioned in front of the user's eyes. In another example, a virtual reality device can be worn on the head of a user such that a display screen is positioned in front of the user's eyes. The frame can include a housing or other structural component supporting or housing the optical component, for example lenses or screens.

In a particular example, the head-mountable electronic device can include a pair of securement arms extending from the frame. The pair of securement arms can apply pressure to or around a user's head to maintain the frame in position, such as in front of the user's eyes. In some examples, the securement arms can rest on top of the user's ears to assist in securing the head-mountable device to the head of the user.

The frame can have a relatively high weight as compared to the securement arms, which results in a balance point of the head-mountable electronic device being biased towards the frame. As a result, a majority of the weight of the head-mountable electronic device can rest on the user's nose, while the rest of the weight of the head-mountable electronic device is carried by the user's ears and head. The balance point of the head-mountable electronic device can be static, such that the same pressures are applied to the user throughout use of the head-mountable electronic device. Different users of the head-mountable electronic device can have different head characteristics (e.g., nose positions, car positions, and the like), which results in the head-mountable electronic device having different balance points on different users.

The head-mountable electronic device can include one or more adjustment mechanisms that can be used to adjust the balance point of the head-mountable electronic device. For example, the adjustment mechanisms can be used to move the balance point of the head-mountable electronic device proximally or distally, and can be used to provide a balanced weight distribution of the head-mountable electronic device on the user's nose and cars. The adjustment mechanisms can be used to adjust the balance point of the head-mountable electronic device throughout use of the head-mountable electronic device to provide different weight distributions of the head-mountable electronic device on the user's head to provide a more comfortable fit of the head-mountable electronic device over time. The adjustment mechanisms can be used to provide balanced configurations of the head-mountable electronic device on different users with different head characteristics.

In some examples, the securement arms can include proximal portions connected to the frame and distal portions connected to the proximal portions. The adjustment mechanisms can be connected to the proximal portions and/or the distal portions, and can provide adjustments between the proximal portions and the distal portions. For example, the adjustment mechanisms can adjust distances and angles between the proximal and distal portions. In some examples, the adjustment mechanisms can be provided between the securement arms and the frame, and can be used to adjust relative positions of the securement arms and the frame. The adjustment mechanisms can include dials, sliding straps, telescoping tubes, hinges, and the like.

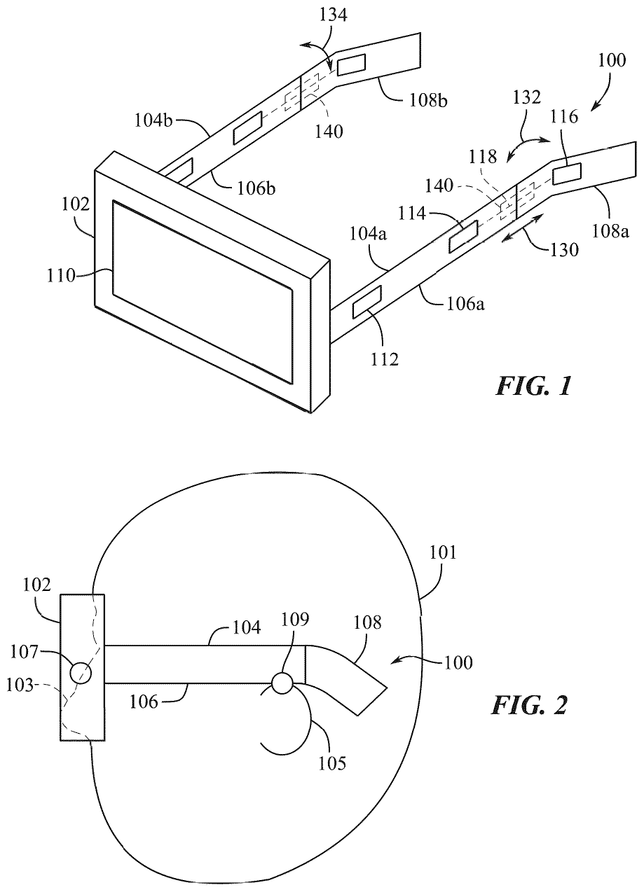

These and other embodiments are discussed below with reference to FIGS. 1-9. However, those skilled in the art will readily appreciate that the detailed description given herein with respect to these Figures is for explanatory purposes only and should not be construed as limiting. Furthermore, as used herein, a system, a method, an article, a component, a feature, or a sub-feature comprising at least one of a first option, a second option, or a third option should be understood as referring to a system, a method, an article, a component, a feature, or a sub-feature that can include one of each listed option (e.g., only one of the first option, only one of the second option, or only one of the third option), multiple of a single listed option (e.g., two or more of the first option), two options simultaneously (e.g., one of the first option and one of the second option), or combination thereof (e.g., two of the first option and one of the second option).

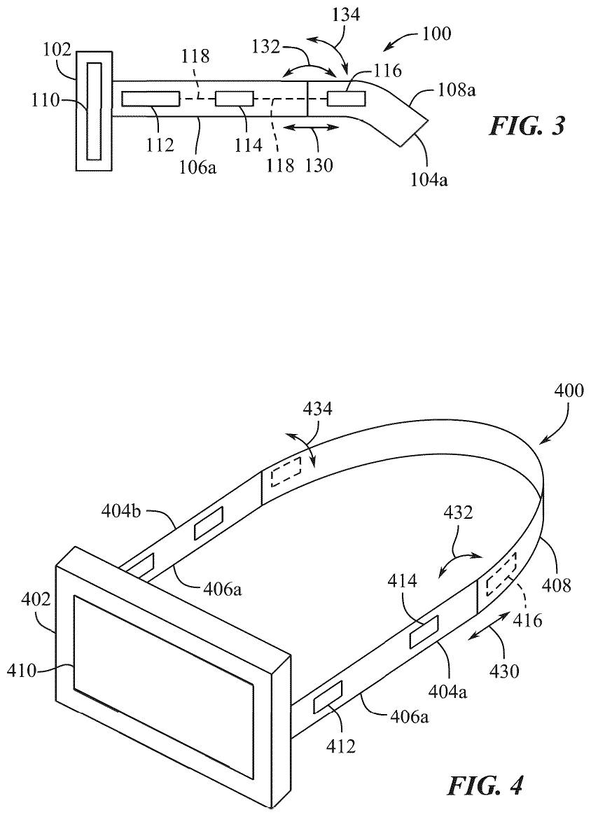

FIGS. 1-3 illustrates various views of an example of a head-mountable device 100. The head-mountable device 100 (referred to hereinafter as the “device” for convenience) can be any device or system configured to be worn on the head of a user, such as a head-mountable electronic device, an optical device, or the like. Thus, the term “device” is used for the sake of convenience, without the intent to limit this term. FIG. 1 illustrates a perspective view of the device 100, FIG. 2 illustrates a side view of the device 100 worn on a user's head 101, and FIG. 3 illustrates a side view of the device 100.

The device 100 can include a frame 102 configured to secure one or more optical lenses or display screens in front of the eyes of the user. The device 100 can include one or more securement arms 104a, 104b (e.g., temple arms, collectively referred to as securement arms 104) extending from the frame 102 distally towards a rear of the user's head 101. For example, the device 100 can include a first securement arm 104a and a second securement arm 104b. The securement arms 104a, 104b and the frame 102 can secure the device 100 to the user's head 101.

The frame 102 can be configured to rest on the user's nose 103. Each of the securement arms 104a, 104b can be secured to the frame 102 and can extend (e.g., distally) toward the rear of the user's head 101. The securement arms 104a, 104b can extend over the user's ears 105 and curve along (e.g., adjacent to) the user's head 101. The securement arms 104a, 104b can be configured to rest on the user's ears 105. The securement arms 104a, 104b can also be configured to apply opposing pressures to the sides of the user's head 101. Thus, the device 100 can be secured to the user's head 101 by a normal force applied from the user's nose 103 to the frame 102, normal forces applied from the user's ears 105 to the securement arms 104a, 104b, and friction forces between the frame 102 and the securement arms 104a, 104b and the user's head 101.

The frame 102 can include relatively heavy components of the device 100, such as a frame, optical lenses, display screens, electronic components, and the like. The securement arms 104a, 104b can be relatively light. As such, a balance point of the device 100 can be generally biased proximally relative to the user's head 101, towards the frame 102. A majority of the weight of the device 100 can be supported by the user's nose 103 relative to the user's ears 105. This unbalanced configuration can result in the device 100 having a greater perceived weight by the user, and can result in increased pressure on the user's nose 103. This results in the device 100 becoming uncomfortable, especially as the device 100 is worn for longer durations. The balance point of the device 100 is generally static with the same pressure being applied from the device 100 to the user throughout the duration of use of the device 100. Providing the device 100 with a balanced balance point that distributes weight evenly between the user's nose 103 and the user's ears 105 can result in the device 100 having a lower perceived weight, and a more comfortable fit. Further, providing the device 100 with a balance point that is dynamic, such as moving between the user's nose 103 and the user's ears 105, can result in the device having a more comfortable fit, especially as the device 100 is worn for longer durations. Different users with different head sizes and shapes can require different fits of the device 100 to achieve a balanced balance point. As such, the device 100 can be provided with an adjustable balance point, which can be evenly balanced upon donning the device 100, and can dynamically change as the device 100 is worn by a user, regardless of varying features in particular users.

In the example of FIGS. 1-3, the securement arms 104a, 104b each include proximal portions 106a, 106b and distal portions 108a, 108b, respectively. As illustrated in FIG. 2, the distal portions 108 can be disposed distally behind the user's ears 105; however, in some examples, boundaries between the proximal portions 106 and the distal portions 108 can be directly over a centerline of the user's ears 105, or proximally in front of the user's ears 105, such that at least portions of the distal portions 108 can extend over the user's ears 105 or proximally in front of the user's ears 105. The distal portions 108a, 108b can be relatively heavy as compared to the proximal portions 106a, 106b, such as by locating relatively heavy components of the device 100 in the distal portions 108a, 108b. More specifically, in some examples, the distal portions 108a, 108b can have masses greater than masses of the corresponding proximal portions 106a, 106b. Because the distal portions 108a, 108b are relatively heavy and are used to weight the device 100, the distal portions 108a, 108b can be referred to as ballasts. Components of the device 100 that can be located in the distal portions 108a, 108b can include batteries, processors, other electrical components, adjustment mechanisms, expansion mechanisms, and the like. The distal portions 108a, 108b can be adjustable relative to the proximal portions 106a, 106b using adjustment mechanisms 140 between the proximal portions 106a, 106b and the distal portions 108a, 108b.

The adjustment mechanisms 140 (also referred to as expansion mechanisms) can be used to adjust the balance point between the frame 102 and the securement arms 104a, 104b (e.g., to adjust the force distribution applied between the user's nose 103 and the user's ears 105). For example, the distal portions 108a, 108b can translate relative to the proximal portions 106a, 106b (e.g., in proximal or distal directions relative to the frame 102 and the user's head 101, illustrated by arrows 130), an angle between the distal portions 108a, 108b and the proximal portions 106a, 106b can be changed (e.g., about an axis perpendicular to longitudinal axes of the securement arms 104 and parallel to a longitudinal axis of the frame 102, illustrated by arrows 132; about an axis perpendicular to longitudinal axes of the securement arms 104 and the frame 102, illustrated by arrows 134, or the like), or the like. The adjustment mechanisms 140 can include dials, slidable straps, telescoping tubes, hinges, and the like. The adjustment mechanisms 140 can be part of or coupled to the proximal portions 106a, 106b and/or the distal portions 108a, 108b. In some examples, including the adjustment mechanisms 140 on the distal portions 108a, 108b can further increase the relative weight of the distal portions 108a, 108b, which can aid in balancing the balancing point of the device 100.

The adjustment mechanisms 140 can be used to adjust the balance point of the device 100. For example, using the adjustment mechanisms 140 to move the distal portions 108a, 108b distally in the direction 130 moves the balance point of the device 100 distally, away from the frame 102. Using the adjustment mechanisms 140 to move the distal portions 108a, 108b proximally in the direction 130 moves the balance point of the device 100 proximally, towards the frame 102. Using the adjustment mechanisms 140 to rotate the distal portions 108a, 108b in the direction 132 alters a contact area of the securement arms 104a, 104b on the user's ears 105, and can move the balance point of the device 100 proximally (e.g., as longitudinal axes of the distal portions 108a, 108b are angled relative to longitudinal axes of the proximal portions 106a, 106b) or distally (e.g., as longitudinal axes of the distal portions 108a, 108b are closer to parallel to longitudinal axes of the proximal portions 106a, 106b). Using the adjustment mechanisms 140 to rotate the distal portions 108a, 108b in the direction 134 alters a frictional/normal force applied between sides of the user's head 101 and the securement arms 104a, 104b and can reduce normal forces applied between the device 100 and the user's nose 103 and the user's ears 105. Rotating the distal portions 108a, 108b in the direction 134 can also move the balance point of the device 100 proximally (e.g., as longitudinal axes of the distal portions 108a, 108b are angled relative to longitudinal axes of the proximal portions 106a, 106b) or distally (e.g., as longitudinal axes of the distal portions 108a, 108b are closer to parallel to longitudinal axes of the proximal portions 106a, 106b). In examples in which the adjustment mechanisms 140 are used to adjust angles between the proximal portions 106a, 106b and the distal portions 108a, 108b, the adjustment mechanisms 140 can be connected to both the proximal portions 106a, 106b and the distal portions 108a, 108b at a joint between the proximal portions 106a, 106b and the distal portions 108a, 108b.

The balance point of the device 100 can be set upon a user donning the device 100, and can be changed throughout the duration of the user wearing the device 100. For example, upon donning the device 100, the adjustment mechanisms can be used to adjust the distal portions 108a, 108b relative to the proximal portions 106a, 106b such that the balance point is between the user's nose 103 and the user's ears 105, and normal forces between the user's nose 103 and the user's ears 105 are equivalent. In other words, about 50% of the weight of the device 100 is supported by the user's nose 103, and about 50% of the weight of the device 100 is supported by the user's ears 105. This can be adjusted throughout the duration of the user's wearing of the device 100 in order to vary the pressure applied by the device 100 to the user. For example, the distal portions 108a, 108b can be adjusted relative to the proximal portions 106a, 106b to apply more pressure to the user's nose 103 and less pressure to the user's ears 105, and vice versa throughout the user wearing the device 100, varying the pressure applied to the user, and increasing user comfort. The distal portions 108a, 108b can also be adjusted relative to the proximal portions 106a, 106b to apply more or less pressure to the user's head 101, to alter where pressure is applied to the user's ears 105, and the like.

The device 100 can include various adjustment mechanisms 140 for adjusting the balance point of the device 100, and the balance point can be adjusted manually or automatically. In other words, the balance point can be adjusted through electric actuators (e.g., automatically), or through manual actuators (e.g., manually). The balance point can be adjusted automatically through the adjustment mechanisms 140 by including motors (e.g., stepper motors), actuators (such as electric actuators), or the like. The automatic adjustment mechanisms 140 can provide discrete or continuous adjustments to the balance point. In some examples, the balance point can be adjusted manually by the user by operating manual adjustment mechanisms 140. The manual adjustment mechanisms 140 can include dials, slidable straps, hinges (e.g., friction hinges), telescoping tubes, other manual actuators, or the like that change the positions of the distal portions 108a, 108b relative to the proximal portions 106a, 106b. The user can adjust the balance point of the device 100 until the balance point feels balanced, or the user can be instructed by the device 100 on setting the balance point. In some examples, the device 100 can include force sensors that detect forces applied between the device 100 and the user's head 101. The device 100 can use data from the force sensors in adjusting the balance point of the device 100, either automatically or by prompting the user to manually adjust the balance point using the adjustment mechanisms 140.

During a user wearing the device 100, the balance point can be adjusted based on a variety of factors. For example, the balance point can be adjusted based on an activity being performed with the device 100 (e.g., depending on dynamic activities, sedentary activities, or the like), a duration of use of the device 100, user preferences, and the like. In some examples, a user profile can be established for each user of the device 100, and the user profile can store data related to each user's personal preferences for the balance point of the device 100. The device 100 can include a machine learning algorithm that determines a suggested balance point based on activities the user is performing, a natural progression of user comfort over time, and the user's preferences. The device 100 can analyze a user's use of the device 100, such as adjustments to the balance point made by the user, movements of the device 100 by the user relative to the user's head 101, and the like in order to update the user's user profile, personal preferences, and the like.

The securement arms 104a, 104b can include one or more electronic components, such as a first electronic component 112, a second electronic component 114, and a third electronic component 116, illustrated in FIG. 1. The electronic components 112, 114, 116 can include any number of electronic components and can be configured to operate and produce a virtual or augmented reality experience to the user through the device 100. The first and second electronic components 112, 114 can include a projector, a waveguide, a speaker, a processor, or a memory component and the third electronic component 116 can include a battery or any other component including those described with reference to the first and second electronic components 112, 114. In examples where the electronic component(s) 112, 114, 116 include a projector and/or a waveguide, the projector and/or waveguide can be configured to project light that is displayed on a window 110 secured to the frame 102. The window 110 can include an optically transparent material. The window 110 can include an optical lens. The window 110 can include a transparent window through which light passes without redirecting the light, or can include or vision correcting geometries. In examples where the third electronic component 116 includes a battery, the battery can be connected to the first electronic component 112 and/or the second electronic component 114 via an electronic circuitry component 116 to deliver power to the first electronic component 112 and/or the second electronic component 114.

In some examples, the electronic circuitry component 116 can include one or more electrically conductive wires, flexes, resistors, circuit boards, or any other electronic circuitry components connecting the third electronic component 116 to the first electronic component 112 and/or the second electronic component 114. In some examples, the electronic circuitry component 116 can include an electrical cable or wire. In some examples, the electrical cable or wire can include a planar flex.

The first electronic component 112, the second electronic component 114, the third electronic component 116, and/or the electronic circuitry component 116 can be disposed within an internal volume of the device 100 (e.g., within an internal volume of the securement arms 104a, 104b) such that the components are hidden from view. Alternatively, one or more of the components 112, 114, 116, 118 can be disposed on the device 100, such as on a housing of the securement arms 104a, 104b. The first electronic component 112 and/or the second electronic component 114 can be included in the frame 102, and an electronic circuitry component the same as or similar to the electronic circuitry component 116 can be included between the frame 102 and the securement arms 104a, 104b to connect any of the electronic components 112, 114, 116.

FIG. 4 illustrates a perspective view of a head-mountable device 400. The device 400 includes a frame 402, a first securement arm 404a and a second securement arm 404b. Each of the securement arms 404a, 404b can include a proximal portion 406a, 406b, respectively, and can be coupled to one another by a distal portion 408. The frame 402 and the proximal portions 406a, 406b can be substantially similar to, including some or all of the features of the frame 102 and the proximal portions 106a, 106b, respectively, of FIGS. 1-3. The distal portion 408 can be a band with a first end attached to the first proximal portion 406a and a second end opposite the first end attached to the second proximal portion 406b. The frame 402 can include windows 410; the proximal portions can include first electronic components 412 and second electronic components 414; and the distal portion 408 can include third electronic components 416. The windows 410, the first electronic components 412, the second electronic components 414, and the third electronic components 416 can be substantially similar to, including some or all of the features of the windows 110, the first electronic components 112, the second electronic components 114, and the third electronic components 116, respectively, of FIGS. 1-3.

The securement arms 404a, 404b and the frame 402 can secure the device 400 to a user's head. The frame 402 can be configured to rest on the user's nose. Each of the securement arms 104a, 104b can be secured to the frame 102 and can extend (e.g., distally) toward the rear of the user's head 101. The securement arms 104a, 104b can extend over the user's ears and curve along (e.g., adjacent to) the user's head. The securement arms 404 can be configured to rest on the user's ears. The securement arms 404 can also be configured to apply opposing pressures to the sides of the user's head. The distal portion 408 can wrap around the back of the user's head opposite the frame 402 and can apply pressure to the back of the user's head. Thus, the device 400 can be secured to the user's head by a normal force applied from the user's nose to the frame 402, normal forces applied from the user's ears to the securement arms 404, and friction forces between the frame 402 and the securement arms 404 and the user's head.

The distal portion 408 can be relatively heavy as compared to the proximal portions 406a, 406b, such as by locating relatively heavy components of the device 400 in the distal portion 408. More specifically, in some examples, the distal portion 408 can have a mass greater than masses of the corresponding proximal portions 406a, 406b. Components of the device 400 that can be located in the distal portion 408 can include batteries, processors, other electrical components, adjustment mechanisms, expansion mechanisms, and the like. The distal portion 408 can be adjustable relative to the proximal portions 406a, 406b, which can be used to adjust the balance point between the frame 402 and the securement arms 404a, 404b (e.g., to adjust the force distribution applied between the user's nose, the user's ears, and the user's head). For example, the distal portion 408 can be slidable relative to the proximal portions 406a, 406b (e.g., in proximal or distal directions relative to the frame 402 and the user's head, illustrated by arrows 430), an angle between the distal portion 408 and the proximal portions 406a, 406b can be changed (e.g., about an axis perpendicular to longitudinal axes of the securement arms 404 and parallel to a longitudinal axis of the frame 402, illustrated by arrows 432; about an axis perpendicular to longitudinal axes of the securement arms 404 and the frame 402, illustrated by arrows 434, or the like), or the like. The distal portion 408 can be disposed distally behind the user's ears; boundaries between the proximal portions 406 and the distal portion 408 can be directly over a centerline of the user's ears; or the boundaries can be disposed proximally in front of the user's ears. As such, in some examples, at least portions of the distal portion 408 can extend over the user's ears or proximally in front of the user's ears.

The balance point of the device 400 can be set and adjusted similar to the device 100, as discussed above with respect to FIGS. 1-3. The balance point for the device 400 can balance forces applied between the device 400 and each of the user's nose, ears, and surfaces of the user's head (e.g., side and back surfaces of the user's head), and can reduce forces applied between the device 400 and the user's nose and ears. As described with respect to the device 100, the device 400 can include automatic and/or manual adjustment, and can include adjustment mechanisms such as dials, slidable straps, hinges, and the like. The device 400 can be adjusted automatically or can provide instructions to users for how to adjust the device 400. The device 400 can store and access user profiles, and can provide adjustment based on user profiles specific to each user of the device 400.

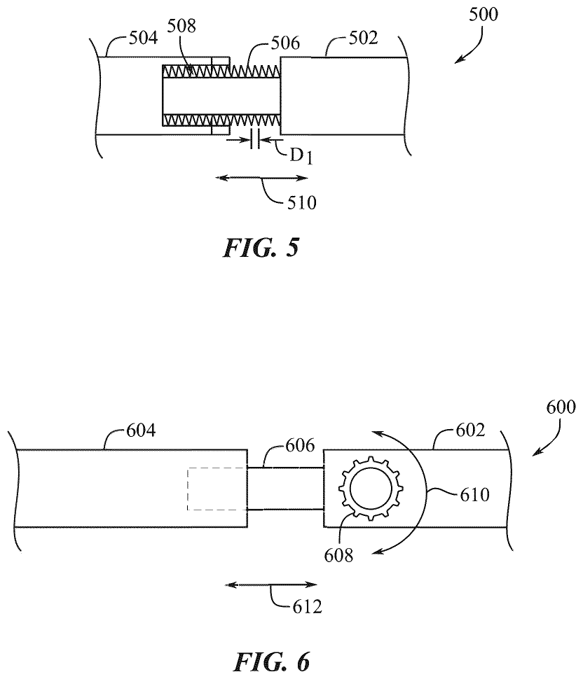

FIG. 5 illustrates a side view of a portion of a securement arm 500 including a notched sliding adjustment mechanism. The adjustment mechanism can be referred to as an expansion mechanism. In the example illustrated in FIG. 5, a notched strap 506 is attached to a first portion 502 of the securement arm 500, and the notched strap 506 is received in an opening 508 in a second portion 504 of the securement arm 500. The notched sliding adjustment mechanism can be used as an adjustment mechanism in either of the devices 100, 400, described above. The notched strap 506 can be used to adjust a distance between the first portion 502 and the second portion 504 in a direction 510 and can be used to maintain the distance between the first portion 502 and the second portion 504 once the distance is adjusted. The first portion 502 or the second portion 504 can be the proximal portions of the devices 100, 400, and the other of the first portion 502 or the second portion 504 can be the distal portions of the devices 100, 400. In some examples, the notched strap 506 can be provided on the distal portions of the devices 100, 400, and can add weight to the distal portions. The notched strap 506 can be included between proximal portions and distal portions of one or both securement arms of the devices 100, 400. The notched strap 506 can be provided between one or two proximal and distal portions 106, 108 of the device 100, and between one or both proximal and distal portions 406, 408 of the device 400.

The notched strap 506 can provide discrete adjustment between the first portion 502 and the second portion 504 having a desired spacing between each adjustment increment. For example, the notched strap 506 can include a plurality of notches with a spacing D₁ between adjacent notches. In some examples, the spacing D₁ can be in a range from about 0.5 mm to about 5 mm, between about 1 mm and about 2 mm, or about 1 mm; however, any suitable spacing can be used.

The notched strap 506 is received in the opening 508. The opening 508 can include a detent that retains the notched strap 506 in a particular position relative to the second portion 504. The notched strap 506 can be moved relative to the second portion 504 by pushing the first portion 502 towards the second portion 504 or pulling the first portion 502 away from the second portion 504 with a sufficient force to overcome the detent. The detent can be disposed in individual notches of the notched strap 506 to retain the notched strap 506 in the opening 508. In some examples, a motor, such as a stepped motor, can be used to move the notch strap 506 relative to the second portion 504. Although the notched sliding adjustment mechanism with the notched strap is illustrated, in some examples, a sliding adjustment mechanism can use telescoping tubes, or the like.

FIG. 6 illustrates a side view of a portion of a securement arm 600 including a dial adjustment mechanism. The adjustment mechanism can be referred to as an expansion mechanism. In the example illustrated in FIG. 6, a dial 608 is attached to a first portion 602 of the securement arm 600, and a strap 606 is attached to a second portion 604 of the securement arm 600. The strap 606 can be received in an opening in the first portion 602, and the dial 608 can move the strap 606 relative to the opening. The dial adjustment mechanism can be used as an adjustment mechanism in either of the devices 100, 400, described above.

The dial 608 can be used to adjust a distance between the first portion 602 and the second portion 604 in a direction 612 and can be used to maintain the distance between the first portion 602 and the second portion 604 once the distance is adjusted. The dial 608 can be manipulated in a direction 610 to move the first and second portions in the direction 612. The first portion 602 or the second portion 604 can be the proximal portions of the devices 100, 400, and the other of the first portion 602 or the second portion 604 can be the distal portions of the devices 100, 400. In some examples, the dial 608 can be provided on the distal portions of the devices 100, 400, and can add weight to the distal portions. The dial 608 can be provided on one or two distal portions 108 of the device 100, and on one or both ends of the distal portion 408 of the device 400. In examples in which a single dial 608 is included in a device 100, 400, the dial 608 can adjust both securement arms of the device 100, 400 simultaneously, such as through a cable extending between two securement arms of the device 100, 400.

The dial 608 can provide discrete adjustment between the first portion 602 and the second portion 604 having a desired spacing between each adjustment increment. For example, the dial 608 can include a detent that allows for incremental angular adjustment of the dial 608 in the direction 610, resulting in incremental distance adjustment of the distance between the first portion 602 and the second portion 604 in the direction 612. In some examples, the incremental angular adjustment can be in a range from about 0.5 degrees to about 10 degrees, from about 1 degree to about 3 degrees, about 3 degrees, or the like; however, any suitable spacing can be used. Incremental adjustment of the dial can adjust the distance between the first portion 602 and the second portion 604 by increments in a range from about 0.5 mm to about 5 mm, between about 1 mm and about 2 mm, or about 1 mm; however, any suitable spacing can be used. In some examples, the dial 608 can be used to adjust an angle between the first portion 602 and the second portion 604, additionally or in the alternative to the dial 608 adjusting the spacing between the first portion 602 and the second portion 604.

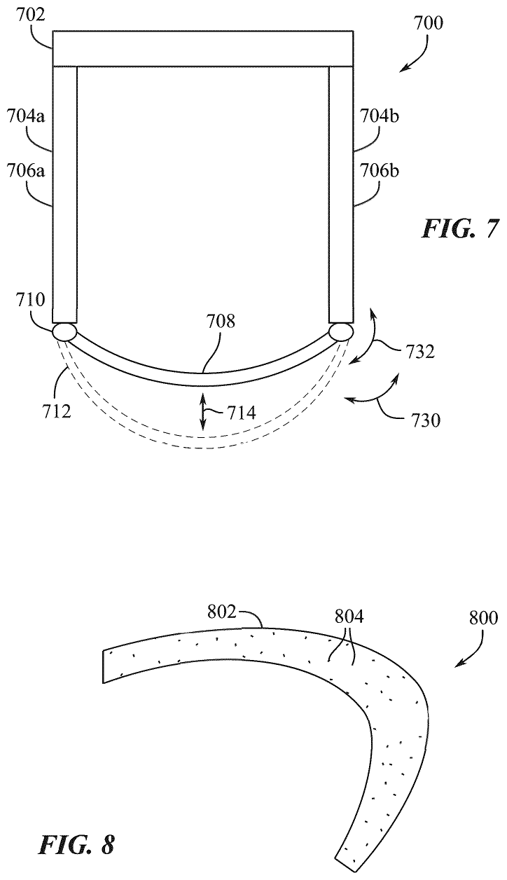

FIG. 7 illustrates a top-down view of a head-mountable device 700 including a diameter-altering adjustment mechanism. The adjustment mechanism can be referred to as an expansion mechanism. The device 700 can be substantially similar to, including some or all of the features of the device 400 of FIG. 4. For example, the device 700 can include a frame 702, securement arms 704a, 704b that include proximal portions 706a, 706b, respectively, and a distal portion 708.

In the example illustrated in FIG. 7, hinges 710 are attached between the proximal portions 706a, 706b and the distal portion 708. The hinges 710 can be provided to alter forces applied between the device 700 and a user's head. For example, in a first position (e.g., represented by the solid lines of the distal portion 708), the frame 702 can rest on the user's nose, the securement arms 704 can rest on the user's ears, and the distal portion 708 can apply force to the back of the user's head opposite the frame 702. The hinges 710 can be rotated such that the distal portion moves in the direction 714 to a second position 712. In the second position, the frame 702 can rest on the user's nose, the securement arms 704 can rest on the user's ears, and the proximal portions 706 can apply force to the sides of the user's head. Moving the distal portion 708 from the first position to the second position 712 can move a balance point of the device 700 distally such that more force is applied to the user's ears, and can result in force being applied to the sides of the user's head by the proximal portions 706 rather than force being applied to the back of the user's head by the distal portion 708. The hinges 710 can be friction hinges or the like, and can maintain a desired position of the distal portion 708 once the securement arms 704 are adjusted.

The hinges 710 can allow for rotation of the distal portion 708 relative to the proximal portions 706 in more than one direction. For example, as illustrated in FIG. 7, the hinges 710 can allow for rotation of the distal portion 708 relative to the proximal portions 706 in a first direction 730 perpendicular to longitudinal axes of the securement arms 704 and the frame 702 and the hinges 710 can allow for rotation of the distal portion 708 relative to the proximal portions 706 in a second direction 732 perpendicular to longitudinal axes of the securement arms 704 and parallel to a longitudinal axis of the frame 702. The distal portion 708 can be formed from a relatively rigid material with a shape configured to cup the user's head.

FIG. 8 illustrates a band 800 that can be used for a distal portion in the devices described above, such as the distal portions 408, 708 in the devices 400, 700 described above with respect to FIGS. 4 and 7. The band 800 includes a body portion 802 with coupling features 804 (also referred to as couplers). The coupling features 804 can be included along an inner surface of the band 800, such as a surface configured to contact a user's head. The coupling features 804 can be protrusions from the body portion 802 and can be formed of the same or different materials from the body portion 802. In some examples, the body portion 802 and/or the coupling features 804 can be formed of rubbers, polymers, silicones, or the like. The coupling features 802 can be formed from materials that grip a user's hair and/or scalp (e.g., the coupling features 802 can be hair-coupling features, hair couplers, scalp-coupling features, and/or scalp couplers), and can be included to improve retention of the devices 400, 700 on a user's head.

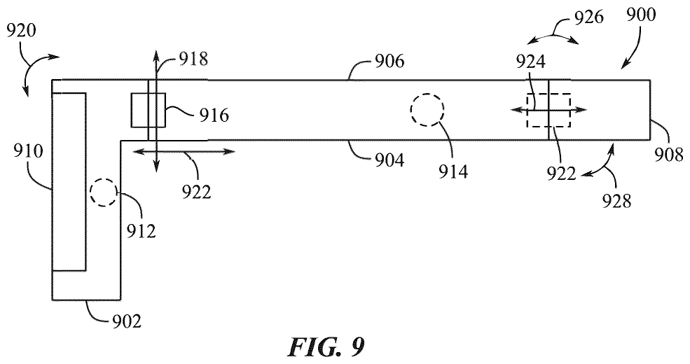

FIG. 9 illustrates a side view of an example of a head-mountable device 900. The device 900 includes a frame 902 and securement arms 904 extending from the frame 902. Each of the securement arms 904 can include a proximal portion 906 and a distal portion 908. The device 900 includes adjustment mechanisms 916, 922 between the frame 902 and the securement arms 904 and between the proximal portions 906 and the distal portions 908 of the securement arms 904, respectively. The frame 902 and the securement arms 904 can be substantially similar to, including some or all of the features of the frame 102 and the securement arms 104, respectively, of FIGS. 1-3.

The adjustment mechanism 916 can adjust any number of: a vertical position 918 of the securement arms 904 relative to the frame 902, an angular position 920 of the securement arms 904 relative to the frame 920, or a horizontal position 922 of the securement arms 904 relative to the frame 920. The vertical position 918 can be perpendicular to longitudinal axes of the securement arms 904 and the frame 902. The angular position 920 can be relative to an axis parallel to the longitudinal axis of the frame 902 and perpendicular to the longitudinal axes of the securement arms 904. The horizontal position 922 can be parallel to the longitudinal axes of the securement arms 904 and perpendicular to the longitudinal axis of the frame 902. The adjustment mechanism 922 can adjust any number of: a horizontal position 924 of the distal portions 908 relative to the proximal portions 906, a first angular position 926 of the distal portions 908 relative to the proximal portions 906, or a second angular position 928 of the distal portions 908 relative to the proximal portions 906. The horizontal position 924 can be parallel to the longitudinal axes of the securement arms 904 and perpendicular to the longitudinal axis of the frame 902. The first angular position 926 can be relative to an axis parallel to the longitudinal axis of the frame 902 and perpendicular to the longitudinal axes of the securement arms 904. The second angular position 928 can be relative to an axis perpendicular to the longitudinal axes of the frame 902 and the securement arms 904.

The adjustment mechanisms 916, 922 can be any of the adjustment mechanisms described previously, such as dials, slidable straps, hinges, telescoping tubes, or the like. The adjustment mechanisms 916, 922 can be used to adjust a balance point of the device 900 and forces applied between the device 900 and a user's head. For example, adjusting any of the vertical position 918, the angular position 920, the horizontal position 922, or the horizontal position 924 adjusts the balance point of the device 900 proximally or distally. In other words, adjusting any of the vertical position 918, the angular position 920, the horizontal position 922, or the horizontal position 924 adjusts the distribution of forces applied between the device 900 and the user's nose and ears. Adjusting the first angular position 926 adjusts the amount of force applied between sides of the user's head and the securement arms 904. Adjusting the second angular position 928 adjusts the contact area between the user's ears and the device 900. The adjustment mechanisms 916, 922 can be used to improve fit and comfort of the device 900 and provide a balanced fit of the device 900. The adjustment mechanisms 916, 922 can be used to adjust the balance and fit of the device 900 during use of the device 900 to prevent fatigue and discomfort resulting from wearing the device 900 in the same position for an extended period of time. Either of the adjustment mechanisms 916, 922 can be optional, and can be used independently of one another.

The device 900 can include one or more electronic components, such as a first electronic component 912 and a second electronic component 914. The electronic components 912, 914 can include any number of electronic components and can be configured to operate and produce a virtual or augmented reality experience to the user through the device 100. The first electronic component 912 can include a projector, a waveguide, a speaker, a processor, or a memory component. The second electronic component 914 can include a battery or any other component including those described with reference to the first electronic component 912. In examples where the first electronic component 912 includes a projector and/or a waveguide, the projector and/or waveguide can be configured to project light that is displayed on a window 910 secured to the frame 902. The window 910 can include an optically transparent material. The window 910 can include an optical lens. The window 910 can include a transparent window through which light passes without redirecting the light or can include or vision correcting geometries. In examples where the second electronic component 914 includes a battery, the battery can be connected to the first electronic component 912 via an electronic circuitry component to deliver power to the first electronic component 912.

To the extent applicable to the present technology, gathering and use of data available from various sources can be used to improve the delivery to users of invitational content or any other content that may be of interest to them. The present disclosure contemplates that in some instances, this gathered data may include personal information data that uniquely identifies or can be used to contact or locate a specific person. Such personal information data can include demographic data, location-based data, telephone numbers, email addresses, TWITTER® ID's, home addresses, data or records relating to a user's health or level of fitness (e.g., vital signs measurements, medication information, exercise information), date of birth, or any other identifying or personal information.

The present disclosure recognizes that the use of such personal information data, in the present technology, can be used to the benefit of users. For example, the personal information data can be used to deliver targeted content that is of greater interest to the user. Accordingly, use of such personal information data enables users to calculated control of the delivered content. Further, other uses for personal information data that benefit the user are also contemplated by the present disclosure. For instance, health and fitness data may be used to provide insights into a user's general wellness, or may be used as positive feedback to individuals using technology to pursue wellness goals.

The present disclosure contemplates that the entities responsible for the collection, analysis, disclosure, transfer, storage, or other use of such personal information data will comply with well-established privacy policies and/or privacy practices. In particular, such entities should implement and consistently use privacy policies and practices that are generally recognized as meeting or exceeding industry or governmental requirements for maintaining personal information data private and secure. Such policies should be easily accessible by users, and should be updated as the collection and/or use of data changes. Personal information from users should be collected for legitimate and reasonable uses of the entity and not shared or sold outside of those legitimate uses. Further, such collection/sharing should occur after receiving the informed consent of the users. Additionally, such entities should consider taking any needed steps for safeguarding and securing access to such personal information data and ensuring that others with access to the personal information data adhere to their privacy policies and procedures. Further, such entities can subject themselves to evaluation by third parties to certify their adherence to widely accepted privacy policies and practices. In addition, policies and practices should be adapted for the particular types of personal information data being collected and/or accessed and adapted to applicable laws and standards, including jurisdiction-specific considerations. For instance, in the US, collection of or access to certain health data may be governed by federal and/or state laws, such as the Health Insurance Portability and Accountability Act (HIPAA); whereas health data in other countries may be subject to other regulations and policies and should be handled accordingly. Hence different privacy practices should be maintained for different personal data types in each country.

Despite the foregoing, the present disclosure also contemplates embodiments in which users selectively block the use of, or access to, personal information data. That is, the present disclosure contemplates that hardware and/or software elements can be provided to prevent or block access to such personal information data. For example, in the case of advertisement delivery services, the present technology can be configured to allow users to select to “opt in” or “opt out” of participation in the collection of personal information data during registration for services or anytime thereafter. In another example, users can select not to provide mood-associated data for targeted content delivery services. In yet another example, users can select to limit the length of time mood-associated data is maintained or entirely prohibit the development of a baseline mood profile. In addition to providing “opt in” and “opt out” options, the present disclosure contemplates providing notifications relating to the access or use of personal information. For instance, a user may be notified upon downloading an app that their personal information data will be accessed and then reminded again just before personal information data is accessed by the app.

Moreover, it is the intent of the present disclosure that personal information data should be managed and handled in a way to minimize risks of unintentional or unauthorized access or use. Risk can be minimized by limiting the collection of data and deleting data once it is no longer needed. In addition, and when applicable, including in certain health related applications, data de-identification can be used to protect a user's privacy. De-identification may be facilitated, when appropriate, by removing specific identifiers (e.g., date of birth, etc.), controlling the amount or specificity of data stored (e.g., collecting location data a city level rather than at an address level), controlling how data is stored (e.g., aggregating data across users), and/or other methods.

Therefore, although the present disclosure broadly covers use of personal information data to implement one or more various disclosed embodiments, the present disclosure also contemplates that the various embodiments can also be implemented without the need for accessing such personal information data. That is, the various embodiments of the present technology are not rendered inoperable due to the lack of all or a portion of such personal information data. For example, content can be selected and delivered to users by inferring preferences based on non-personal information data or a bare minimum amount of personal information, such as the content being requested by the device associated with a user, other non-personal information available to the content delivery services, or publicly available information.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not intended to be exhaustive or to limit the embodiments to the precise forms disclosed. It will be apparent to one of ordinary skill in the art that many modifications and variations are possible in view of the above teachings.

What is claimed is:

1. A head-mountable electronic device, comprising:
a frame;
a window coupled to the frame;
a projector configured to guide light displayed at the window; and
a securement arm extending from the frame, the securement arm comprising:
a proximal portion connected to the frame;
a distal portion connected to the proximal portion; and
an expansion mechanism connecting the proximal portion to the distal portion, the expansion mechanism configured to extend the distal portion away from the proximal portion, the distal portion having a mass greater than a mass of the proximal portion.

2. The head-mountable electronic device of claim 1, wherein the distal portion is configured to be disposed behind a user's ear when the head-mountable electronic device is donned by the user.

3. The head-mountable electronic device of claim 1, further comprising:
a first electronic component disposed in the distal portion; and
a second electronic component disposed in the proximal portion.

4. The head-mountable electronic device of claim 1, wherein the expansion mechanism comprises an electric actuator.

5. The head-mountable electronic device of claim 1, wherein the expansion mechanism comprises a manual actuator.

6. The head-mountable electronic device of claim 1, wherein:
the securement arm is a first securement arm;
the distal portion is a first distal portion;
the expansion mechanism is a first expansion mechanism; and
the head-mountable electronic device further comprises:
a second securement arm comprising a second proximal portion connected to a second distal portion at a second expansion mechanism.

7. The head-mountable electronic device of claim 6, further comprising a connection band comprising the first distal portion and the second distal portion, the connection band extending from the first proximal portion to the second proximal portion.

8. A head-mountable electronic device, comprising:
a frame;
a window coupled to the frame;
a waveguide configured to guide light displayed at the window; and
a securement arm extending from the frame, the securement arm comprising:
a proximal portion connected to the frame, the proximal portion comprising a first electronic component;
a distal portion connected to the proximal portion, the distal portion comprising a second electronic component electrically coupled to the first electronic component; and
an adjustment mechanism configured to move the distal portion distally relative to the frame.

9. The head-mountable electronic device of claim 8, wherein:
the adjustment mechanism comprises a dial coupled to the distal portion and the proximal portion; and
the dial is configured to adjust an angle of the distal portion relative to the proximal portion when the dial is manipulated.

10. The head-mountable electronic device of claim 8, wherein:
the adjustment mechanism comprises a dial coupled to the distal portion or the proximal portion; and
the dial is configured to adjust a distance between the distal portion and the proximal portion when the dial is manipulated.

11. The head-mountable electronic device of claim 8, wherein:
the adjustment mechanism comprises a notched strap coupled to the distal portion and the proximal portion; and
the notched strap is configured to adjust a distance between the distal portion and the proximal portion when the distal portion is manipulated relative to the proximal portion.

12. The head-mountable electronic device of claim 8, wherein the adjustment mechanism comprises a friction hinge pivotally attaching the distal portion to the proximal portion.

13. The head-mountable electronic device of claim 8, wherein an inner surface of the distal portion comprises a hair coupler.

14. The head-mountable electronic device of claim 8, wherein:
the securement arm is a first securement arm;
the head-mountable electronic device further comprises a second securement arm extending from the frame; and
the distal portion extends from the first securement arm to the second securement arm.

15. A head-mountable display device, comprising:
a frame;
a window coupled to the frame;
a projector configured to guide light displayed at the window;
a first securement arm extending from the frame, the first securement arm including a first distal end;
a second securement arm extending from the frame, the second securement arm including a second distal end;
an adjustable ballast extending between and secured to the first distal end and the second distal end; and
an adjustment mechanism configured to change a position of the ballast relative to the frame.

16. The head-mountable display device 15, wherein the adjustment mechanism is configured to adjust an angle of the adjustable ballast relative to the first securement arm and the second securement arm.

17. The head-mountable display device 15, wherein the adjustment mechanism is configured to extend the adjustable ballast distally away from the first distal end and the second distal end.

18. The head-mountable display device 17, wherein the adjustment mechanism comprises a friction fit between the adjustable ballast and the first distal end.

19. The head-mountable display device of claim 15, wherein:
the adjustment mechanism is a first adjustment mechanism; and
the head-mountable display device further comprises a second adjustment mechanism coupling the first securement arm to the frame.

20. The head-mountable display device of claim 19, wherein the second adjustment mechanism is configured to adjust an angle of the frame relative to the first securement arm.
